(19) United States
(12) Patent Application Publication
(10) Pub. No.: US 2025/0076157 A1
(43) Pub. Date: Mar. 6, 2025

(54) PASSIVE SENSOR DEVICE AND PASSIVE SENSOR SYSTEM

(71) Applicant: Aktiebolaget SKF, Göteborg (SE)

(72) Inventors: Xing YI, Shanghai (CN); Xiaoyuan MA, Shanghai (CN); Hongwei WU, Shanghai (CN); Liang ZHANG, Zou Cheng (CN)

(21) Appl. No.: 18/810,188

(22) Filed: Aug. 20, 2024

(30) Foreign Application Priority Data
Aug. 31, 2023 (CN) 202311119072.3

(51) Int. Cl. G01M 99/00; H02J 7/00; H02J 50/00

(52) U.S. Cl. CPC G01M 99/005; H02J 50/001; H02J 7/0048

(57) ABSTRACT

A passive sensor device and a passive sensor system are disclosed, wherein the passive sensor device comprises a sensing control module configured to operatively perform a detection process on a device to be detected and generate a detection result; an energy harvesting module mounted on a main body of the device to be detected and configured to convert the harvested vibration energy from the device to be detected into alternating current energy; a power management module configured to receive the alternating current energy from the energy harvesting module, convert the alternating current energy to direct current energy, and supply power to the passive sensor device based on the direct current energy.

### CROSS-REFERENCE TO RELATED APPLICATION

This application claims priority to Chinese Application No. 202311119072.3, filed Aug. 31, 2023, the entirety of which is hereby incorporated by reference.

### TECHNICAL FIELD

The present disclosure relates to the field of detection control, more particularly to a passive sensor device and a passive sensor system.

### BACKGROUND

With the widespread use of detection technologies in civilian and commercial fields, detection controls, in particular sensor systems and sensor devices, are also subject to higher demands.

Current sensor devices, such as predictive health management sensors for motors, generally include two types: wired sensors and battery-based wireless sensors. For wired sensors, their installation is inconvenient due to the need for special wiring to connect to an external independent power source. Although the battery-based wireless sensor can solve the wiring problem, it involves another problem, that is, the life of the battery is limited (typically 3-5 years) and there are instances of electrical loss, so it is necessary to replace the battery or replace the new sensor from time to time.

Therefore, there is a need for a passive sensor device that does not require complicated wiring for power supply and does not require the replacement of a battery or a sensor in consideration of battery depletion on the premise of achieving a good sensor detection function. The sensor device can be self-powered through energy conversion without an additional external power source.

### SUMMARY

Given the above problems, the present disclosure provides a passive sensor device and a passive sensor system. With the passive sensor device provided by the present disclosure, it is possible to realize self-power supply via energy conversion on the basis of realizing good sensor detection control without additionally setting an external power source, so that it is formed into a passive sensor device without complicated wiring and without requiring a regular replacement of a battery in consideration of battery depletion.

According to an aspect of the present disclosure, a passive sensor device is proposed, comprising a sensing control module configured to operatively perform a detection process on a device to be detected and generate a detection result; an energy harvesting module mounted on a main body of the device to be detected and configured to convert the harvested vibration energy from the device to be detected into alternating current energy; a power management module configured to receive the alternating current energy from the energy harvesting module, convert the alternating current energy to direct current energy, and supply power to the passive sensor device based on the direct current energy.

In some embodiments, the power management module comprises a rectifier module configured to convert the alternating current energy into first direct current energy; a regulator module configured to receive the first direct current energy from the rectifier module, perform a voltage regulation on the first direct current energy to generate second direct current energy; an energy tracking module configured to receive the second direct current energy from the regulator module and charge an energy storage element based on the second direct current energy; a charging management module configured to supply power to the passive sensor device by using direct current energy in the energy storage element.

In some embodiments, the charging management module is further configured to detect current quantity of electric charge of the energy storage element; compare the current quantity of electric charge of the energy storage element with a preset quantity of electric charge threshold, transmit a power-reaching signal to the sensing control module in the case that the current quantity of electric charge is greater than the preset quantity of electric charge threshold.

In some embodiments, the sensing control module is pre-configured to be in a low-charge operating mode, and the sensing control module is further configured to: receive the power-reaching signal from the charge management module; switch from the low-charge operating mode to a normal operating mode in response to the power-reaching signal, wherein power consumption in the normal operating mode is higher than that in the low-charge operating mode.

In some embodiments, the sensing control module comprises a sensor module configured to operatively detect a performance state of the device to be detected, and generate a detection signal; a controller module configured to operatively receive the detection signal and determine a detection result of the device to be detected based on the detection signal.

In some embodiments, in the low-charge operating mode, the controller module is configured to be in a sleep mode and the sensor module is configured to be in an unpowered mode; wherein the controller module and the sensor module switch to a low-power operating mode upon receiving the power-reaching signal.

In some embodiments, when the controller module and the sensor module are in the low-power operating mode, the controller module and the sensor module are configured to switch from the low-power operating mode to a high-power operating mode when the controller module receives a detection trigger event.

In some embodiments, the detection trigger event comprises at least one of a periodic trigger signal from the controller module, an abnormality detection signal from the sensor module, and a detection request signal from an external device.

In some embodiments, in the high-power operating mode, the controller module is configured to determine the detection result of the device to be detected based on the detection signal, and transmit the detection result.

According to another aspect of the present disclosure, a passive sensor system is provided, comprising: a passive sensor device as described above; a gateway device configured to receive the detection result from the passive sensor device and transmit the detection result to an external device; and the external device comprising at least one of a cloud platform and a user device, and configured to receive the detection result from the gateway device, and display or store the detection result; wherein the gateway device is further configured to receive instruction information from the external device and transmit the instruction information to the passive sensor device.

### BRIEF DESCRIPTION OF DRAWINGS

In order to more clearly illustrate the technical solutions of the embodiments of the present disclosure, the following will simply introduce the accompanying drawings to be used in the description of the embodiments, and it is obvious that the accompanying drawings in the following description are only some embodiments of the present disclosure, and other drawings can be obtained according to these drawings for those of ordinary skill in the art without making inventive labor. The following drawings are not intended to be scaled to actual dimensions, emphasis instead being placed upon illustrating the subject matter of the present disclosure.

FIG. 1 illustrates a schematic diagram of a passive sensor device 100 according to the embodiments of the present disclosure;

FIG. 2 illustrates a schematic diagram of the energy harvesting module 120 according to the embodiments of the present disclosure wherein the energy harvesting module is a piezoelectric transducer;

FIG. 3 illustrates a schematic diagram of a power management module 130 according to the embodiments of the present disclosure;

FIG. 4 illustrates a flow chart of a passive sensor device 100 for a motor according to an embodiment of the present disclosure; and

FIG. 5 illustrates a schematic diagram of a passive sensor system 200 according to an embodiment of the present disclosure.

### DETAILED DESCRIPTION

The technical solutions in the embodiments of the present disclosure will be clearly and completely described below in conjunction with the accompanying drawings, it is obvious that the described embodiments are only partial embodiments of the present disclosure, rather than all of the embodiments. Based on the embodiments of the present disclosure, all other embodiments obtained by those of ordinary skill in the art without making inventive labor also belong to the scope of protection of the present disclosure.

As used in this application and the claims, the words “a,” “an,” and/or “the” do not refer to the singular, but may include the plural unless the context clearly dictates otherwise. In general, the terms “comprise” and “comprising” only imply the inclusion of the steps and elements specifically identified, these steps and elements do not constitute an exclusive list and a method or device may also contain other steps or elements.

Although the present application makes various references to certain modules in a system according to the embodiments of the present application, any number of different modules may be used and run on a user terminal and/or server. The modules are illustrative only and different aspects of the system and method may use different modules.

Flowcharts are used herein to illustrate operations performed by a system according to the embodiments of the present application. It should be understood that the preceding or following operations do not have to be performed exactly in order. Rather, the various steps may be processed in reverse order or simultaneously, as desired. At the same time, other operations may also be added to the processes, or certain step or steps of operations may be removed from the processes.

FIG. 1 illustrates a schematic diagram of a passive sensor device 100 according to the embodiments of the present disclosure. It will be understood that the passive sensor device refers to a sensor device that enables good self-power supply through energy conversion without the additional provision of an external power source.

Referring to FIG. 1, the passive sensor device 100 includes, for example, a sensing control module 110, an energy harvesting module 120, and a power management module 130.

The sensing control module 110 is configured to operatively perform a detection process on the device to be detected and generate a detection result.

The device to be detected refers to a target device to be detected. This device to be detected can be, for example, a motor, a lathe, a gear grinder, or the like, or the corresponding device to be detected can also be determined according to actual needs. The embodiments of the present disclosure are not limited by the specific device type of the device to be detected.

The detection process refers to a process of detecting the current performance state of the device to be detected, and the detection process may include, for example, collecting a plurality of data related to the performance state of the device to be detected and generating a detection result based on further processing of the data, and the detection result may include, for example, one or more result parameters of an operating state detection result, a remaining useful life state detection result, an abnormal failure state detection result, a health state detection result, and the like. Embodiments of the present disclosure are not limited by the specific composition of the detection process and the specific content of the detection result.

The energy harvesting module 120 is intended to implement conversion processes from other energy to electrical energy. Specifically, the energy harvesting module 120, for example, may be mounted on the main body of the device to be detected and configured to convert the harvested vibration energy from the device to be detected into alternating current energy.

For example, when the device to be detected is a motor device, the energy harvesting module 120 may be mounted on a spindle bearing support of the motor device, or at a heat sink of the motor device, for example, to better collect vibration energy of the motor device.

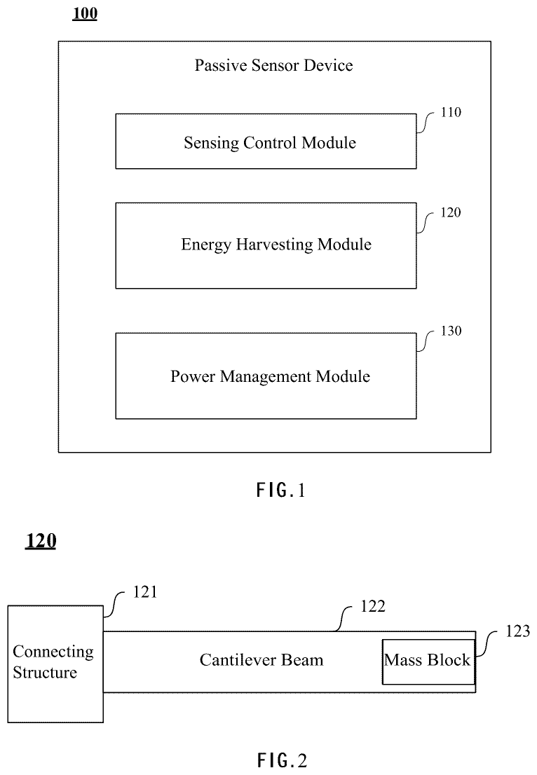

For example, this energy harvesting module may be, a piezoelectric transducer or a magnetoelectric transducer to convert vibration energy from the device to be detected into alternating current energy based on a piezoelectric/magnetoelectric conversion manner. FIG. 2 illustrates a schematic diagram when the energy harvesting module 120 according to the embodiments of the present disclosure is a piezoelectric transducer. This energy conversion process will be described in more detail next with reference to FIG. 2.

Referring to FIG. 2, for example, the energy harvesting module 120 includes a piezoelectric transducer comprising a connecting structure 121, a cantilever beam 122, and a mass block 123. The connecting structure 121 is configured to be fixed to a body of the device to be detected. One end of the cantilever beam 122 is disposed on the connecting structure and the other end of the cantilever beam extends in a direction away from the connecting structure. The cantilever beam is made of piezoelectric material, for example. The other end of the cantilever beam is provided with the mass block 123 intended to enhance the vibration amplitude of the cantilever beam, thereby enabling more vibration energy to be harvested. Specifically, when the device to be detected is in operation (for example, the motor is running), the cantilever beam made of piezoelectric material will vibrate therewith and generate electric energy (here, alternating current energy).

However, it should be understood that the foregoing merely gives an example of the use of piezoelectric transducers to achieve energy conversion. Other configurations, compositions, or types of piezoelectric or magnetoelectric transducers may be selected to achieve the conversion of vibrational energy to alternating current energy, depending on the circumstances. It should be understood that embodiments of the present disclosure are not limited by the particular manner of conversion of the energy and the particular types of transduction components.

The power management module 130 is configured to receive the alternating current energy from the energy harvesting module 120, convert the alternating current energy to direct current energy, and supply power to the passive sensor device 100 based on the direct current energy.

It should be understood that the power management module may rectify the alternating current energy harvested in the energy harvesting module to obtain the direct current energy, for example, based on a rectifier module. The power management module may further provide, for example, a regulator module, an energy tracking module, or the like to further adjust the direct current energy and maximize the obtained power.

It will be understood that the process of supplying power to the passive sensor device 100 may for example be described in more detail. For example, when the quantity of electric charge in the power management module is low (e.g. less than or equal to a preset quantity of electric charge threshold), the direct current energy in the power management module is for example only used to supply power to some of the modules in the passive sensor device. After the quantity of electric charge in the power management module rises and reaches a preset criterion (e.g., greater than the preset quantity of electric charge threshold), the direct current energy in the power management module may then be used, for example, to supply power to various modules in the passive sensor device.

Based on the above, in the present application, the sensor device is set to be a passive sensor device. Specifically, on the basis of setting the sensor device to have a sensing control module that performs a detection process on the device to be detected and generates a detection result, the sensor device is further set to include an energy harvesting module and a power management module, so that it is possible to convert the harvested vibration energy from the device to be detected into the alternating current energy through the energy harvesting module mounted on the main body of the device to be detected, and convert the alternating current energy into direct current energy through the power management module, and supply power to the passive sensor device based on the direct current energy. Compared to current wired sensors and battery-based wireless sensors, the passive sensor device in the present application is able to achieve good and reliable self-powering through energy conversion (especially supply power to the sensing control module), without additional provision of an external power source and complex power supply wiring, and also avoids the problem of requiring replacement of batteries or sensors from time to time.

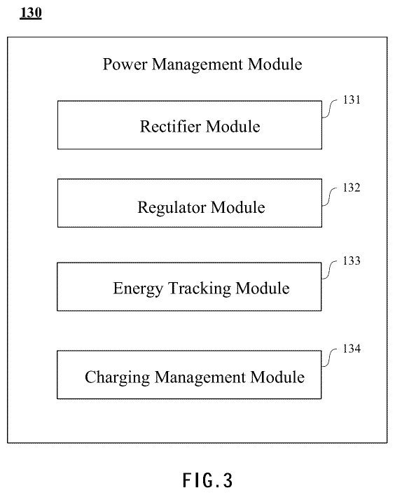

FIG. 3 illustrates a schematic diagram of a power management module 130 according to the embodiments of the present disclosure.

Referring to FIG. 3, in some embodiments, the power management module 130 includes, for example, a rectifier module 131, a regulator module 132, an energy tracking module 133, and a charging management module 134.

The rectifier module 131 refers to a module for realizing a rectification process from alternating current to direct current, and may be, for example, a rectifier component or a rectifier circuit. The rectifier module 131 is configured to convert the alternating current energy into the first direct current energy. It will be understood that the range of voltage values of the alternating current energy may vary, for example, in the range of 0.2 V to 10 V, depending on the specific amplitude of the vibration energy.

The regulator module 132 is configured to receive the first direct current energy from the rectifier module 131, and perform voltage regulation on the first direct current energy to generate the second direct current energy. It should be understood that the first and second direct current energy in the present application are intended to distinguish between two direct currents having different direct current voltages and are not intended to be limiting.

For example, the regulator module performs voltage adjustment on the first direct current energy with a larger voltage value (for example, the direct current voltage being 10V) to obtain the second direct current energy adapted to the sensor device (for example, the direct current voltage being 3.3 V). It should be understood, however, that the foregoing merely gives one example of voltage regulation. Embodiments of the present disclosure are not limited by the specific voltage values corresponding to the first and second direct current energy.

The energy tracking module 133 is configured to receive the second direct current energy from the regulator module 132 and charge the energy storage element based on the second direct current energy.

In particular, since the electric power generated by the energy harvesting module is small, it is not possible to directly supply power to the passive sensor device (in particular, to its sensing control module), and thus energy will be accumulated in the energy tracking module until it is sufficient for the detection control process.

For example, the energy tracking module may be configured to adjust a timing logic and a duty cycle for turning on and off a switch of a charging circuit within the energy tracking module, based on the voltage value of the second direct current energy accordingly to enable charging of the energy storage element at an optimal charging efficiency. It should be understood that embodiments of the present disclosure are not limited by the specific charging scheme and charging circuit components of the energy tracking module.

It will be understood that the energy storage element may be, for example, a low-leakage rechargeable battery or a super capacitor. However, it should be understood that embodiments of the present disclosure are not limited by the particular content of the energy storage element.

The charging management module 134 is configured to supply power to the passive sensor device with direct current energy in the energy storage element. It will be understood that, as previously described, the process of supplying power to the passive sensor device 100 may include: for example, when the quantity of electric charge in the energy storage element is low (e.g. less than or equal to a preset quantity of electric charge threshold), the direct current energy in the energy storage element is, only used to supply power to a part of the modules in the passive sensor device. After the quantity of electric charge in the energy storage element rises and reaches a preset criterion (e.g. is greater than a preset quantity of electric charge threshold), at this time, the direct current energy in the energy storage element can then be used, for example, to supply power to various modules in the passive sensor device.

Based on the above, in the present application, the power management module further comprises a rectifier module, a regulator module, an energy tracking module, and a charging management module, so that the power management module can perform a good rectification and voltage adjustment process on the alternating current energy obtained by energy conversion, and charge the corresponding energy storage element based on the adjusted voltage, so that power can be further accumulated in the energy storage element, and finally the accumulated power of the energy storage element can be applied to supply power to the passive sensor device, thereby realizing a good and reliable self-power supply process and ensuring a good and stable energy source for the passive sensor.

In some embodiments, the charging management module 134 is further configured to detect a current quantity of electric charge of the energy storage element, comparing the current quantity of electric charge of the energy storage element with a preset quantity of electric charge threshold, and transmit a power-reaching signal to the sensing control module in the case that the current quantity of electric charge is greater than the preset quantity of electric charge threshold.

The current quantity of electric charge of the energy storage element refers to data that characterizes the current quantity of electric charge stored by the energy storage element. Embodiments of the present disclosure are not limited by this specific embodiment of detecting the current quantity of electric charge

The preset quantity of electric charge threshold refers to threshold data set in advance by the sensor device or the user, which is intended to divide the storage state of the quantity of electric charge within the energy storage element. For example, exceeding the preset quantity of electric charge threshold indicates that the current quantity of electric charge in the energy storage element is high, which may for example support the sensor device, in particular the sensing control module, to perform various functions in the normal operating mode (e.g. a detection process on the device to be detected, etc.). Below the preset quantity of electric charge threshold is indicative of an insufficient current quantity of electric charge within the energy storage element, which is unable to support the sensor device, and in particular, the sense control module to perform functions in the normal operating mode, and is only able to support the sense control module to maintain operations of core functions (e.g., core controller module operation in the sense control module) in the low-charge operating mode.

The power-reaching signal is intended to indicate that the current quantity of electric charge of the energy storage element reaches a preset criterion, for example, that the current quantity of electric charge of the energy storage element reaches a criterion to support operations of the sensing control module in a normal operating mode.

It will be understood that the power reference signal may be, for example, a character signal, or may also be a text signal, or may also be a binary-coded signal. Embodiments of the present disclosure are not limited by the specific contents of the power-reaching signal and its manifestation.

Based on the above, in the present application, the charging management module detects the current quantity of electric charge of the energy storage element and transmits a power-reaching signal to the sensing control module in the case that the current quantity of electric charge is greater than the preset quantity of electric charge threshold, it is possible to flexibly and efficiently transfer the state of the current quantity of electric charge to the sensing control module, thereby facilitating that the sensing control module can flexibly adjust its operating mode based on the state of the quantity of electric charge, thereby achieving efficient utilization of the power.

In some embodiments, the sensing control module 110 may be pre-configured to be in a low-charge operating mode, for example.

For example, during an initialization or start-up phase of the passive sensor device, the sensing control module 110 is in a low-charge operating mode through the manual setting by the user or preset by the system. Embodiments of the present disclosure are not limited by a specific pre-configuration manner.

The low-charge operating mode means that the sensing control module operates at only the minimum power required to maintain its basic functionality. Specifically, for example, when the sensing control module includes a sensor module and a controller module, in the low-charge operating mode, the sensor module will be configured not to be powered up (not to be powered on), the quantity of electric charge in the energy storage element will only be supplied to the controller module, and the controller module will, for example, only be configured to perform necessary functions such as hardware reset, not receive other signals and data except the power management module (charging management module), and not communicate with the outside. In this low-charge operating mode, the current of the entire passive sensor device is e.g. below 5 uA.

However, it should be understood that the above only gives an example of a low-charge operating mode and its current level. Embodiments of the present disclosure are not limited thereto.

The sensing control module 110 is further configured to receive the power-reaching signal from the charge management module 134 and switch from the low-charge operating mode to a normal operating mode in response to the power-reaching signal, wherein the power consumption in the normal operating mode is higher than that in the low-charge operating mode.

It should be understood that the normal operating mode refers to a mode in which the sensing control module performs conventional functions, such as performing its detection process, detecting the performance state of the device to be detected, and generating a detection signal, etc. It should be understood that the normal operating mode of the sensing control module may, for example, further comprise a plurality of sub-modes, such as a low-power operating mode, a high-power operating mode, etc., which respectively correspond to different functions and also generate different energy consumptions, as will be described in more detail below and will not be repeated here.

Based on the above, in the present application, the sensing control module is pre-configured to be in the low-charge operating mode and is switched from the low-charge operating mode to the normal operating mode with higher power consumption in response to the power-reaching signal, it is possible to flexibly adjust the operating mode and the power consumption level of the sensing control module according to the level of the converted energy, it is possible to well maintain the operation of the core functions of the passive sensor device and save power in the case that the converted energy is low, and it is possible to further enrich the functions of the passive sensor device when the converted energy is sufficient, thereby compromising the balance of power consumption and functions.

In some embodiments, the sensing control module 110 comprises a sensor module 111 and a controller module 112.

The sensor module 111 is configured to operatively detect the performance state of the device to be detected, and generate a detection signal.

For example, the sensor module may be an integrated sensor circuit, or may also comprise a plurality of discrete sensor components. For example, it includes vibration, temperature, magnetic field, noise acquisition sub-circuits, and the like. The process of detecting the performance state of the device to be detected can be carried out, for example, by collecting a plurality of performance signals characterizing the performance of the device to be detected, such as vibration signals, temperature signals, rotational speed signals, magnetic field signals, etc., or it can be carried out on the side of the sensor module on the basis of the sampled signals comparing with preset signal thresholds, generating a normal/abnormal detection signal based on the comparison (for example, indicating whether the performance is in a normal state), and transmitting the normal/abnormal detection signal to the controller module. However, it should be understood that embodiments of the present disclosure are not limited by the particular content of the sensor module.

The controller module 112 is configured to operatively receive the detection signal, and determine a detection result of the device to be detected based on the detection signal.

For example, the controller module may perform a calculation based on the detection signal, by using a neural network algorithm or a synthetic function, and generate a final detection result. It should be understood that embodiments of the present disclosure are not limited by the specific manner in which the controller module generates the detection results.

It will be understood that depending on the actual situation, the sensor module and the controller module may, for example, perform different operations in different operating modes. For example in a low-power operating mode, the sensor module only performs a low-accuracy detection process, i.e. detects at a lower sampling rate and low bandwidth, such as only samples one or several core data signals or analyzes and generates a normal/abnormal detection signal based on one or several core data signals, and only transmits the abnormal detection signal to the controller module indicating that the respective data signal is in an abnormal state. In the low-power mode, the controller module will not further analyze and process the signal from the sensor module. For example, in the high-power operating mode, the sensor module performs a high-accuracy detection process, i.e., detects at a high sampling rate and high bandwidth, and transmits all detection signals (e.g., including data signals and/or normal/abnormal detection signals) to the controller module, which further processes and generates detection results based on the detection signals.

Based on the above, in the present application, the sensing control module includes the sensor module and the controller module and the sensing control module can operably implement the detection process of the device to be detected based on the actual situation and determine the corresponding detection result based on the detection signal, so that a good and reliable detection of the device to be detected may be achieved.

In some embodiments, in the case that the sensing control module includes a sensor module and a controller module, the foregoing operating modes may be described more specifically, for example.

For example, in the low-charge operating mode, the controller module is configured to be in a sleep mode and the sensor module is configured to be in an unpowered mode.

The sleep mode refers to a mode in which the controller module operates with minimal power consumption, and the controller module is, for example, configured to only receive signals from the power management module (the power-reaching signal), and not receive signals from other modules or external devices, and not communicate with other modules or external devices.

The sensor module is in an unpowered mode, which refers to a state in which the sensor module is not connected to a power source and is not powered at all (i.e., does not consume power at all).

The controller module and the sensor module switch to the low-power operating mode upon receipt of the power-reaching signal.

It will be understood that the low-power operating mode and the high-power operating mode hereinafter are each one of the normal operating modes. The normal operating mode refers to an operating mode in which the controller module and the sensor module operate normally and perform corresponding functions. Here, the low-power operating mode refers to an operating mode with lower power consumption during normal operation, in which part of the high-power consumption functions of the controller module and the sensor module, for example, are selectively disabled or not performed, and only their basic functions, such as only the low-accuracy detection process, are performed, thereby realizing power saving. The high-power operation refers to an operating mode with higher power consumption during normal operation, in which functions of the controller module and the sensor module, particularly high power consumption functions, are performed, such as performing a high-accuracy detection process and a phase processing process.

For example, in the low-power operating mode, as previously described, the sensor module only performs a low-accuracy detection process, i.e. detects at a lower sampling rate, low bandwidth, only samples one or several core data signals or analyzes and generates a normal/abnormal detection signal based on one or several core data signals, and only transmits the abnormal detection signal to the controller module indicating that the respective data signal is in an abnormal state. In the low-power mode, the controller module, for example, does not analyze and process the signals from the sensor module and does not transmit relevant signals to an external device.

Based on the above, in the present application, in the low-charge operating mode, the controller module is configured to be in the sleep mode and the sensor module is configured to be in the unpowered mode. Upon receipt of a power-reaching signal, the controller module and the sensor module switch to the low-power operating mode. In case of insufficient power being obtained through energy conversion, the sensor module is not powered up and the controller module operates in the most power-saving sleep mode, thus good power savings are achieved. When the power is relatively sufficient, the detection function is performed by making the controller module and the sensor module operate normally in the low-power operating mode, thereby compromising both function realization and power saving.

In some embodiments, when the controller module receives a detection trigger event when the controller module and the sensor module are in a low-power operating mode, the controller module and the sensor module are configured to switch from the low-power operating mode to the high-power operating mode.

The detection trigger event refers to an event that triggers the sensing control module to operate at higher power (e.g., operate in high power mode) to achieve a high-accuracy detection process.

It should be understood that the detection trigger event may be, for example, an event set in advance by the user, or it may be an event set in the initialization phase of the sensor device, or it may be an event generated based on an abnormal alarm or signal detected by the sensor module or an event determined by instructions from an external device, according to actual needs.

The high-power operating mode refers to an operating mode with higher power consumption during normal operation, in which functions of the controller module and the sensor module, particularly high-power consumption functions, are performed. For example, in a high-power operating mode, the sensor module detects at a high sampling rate and high bandwidth, and transmits all detection signals to the controller module, which further processes detection signals, generates detection results based on the detection signals, and transmits the detection results to the external device.

Based on the above, in the present application, by providing that the controller module and the sensor module are configured to switch from the low-power operating mode to the high-power operating mode when the controller module receives a detection trigger event, it is possible to switch the operation states of the controller module and the sensor module in time when a more comprehensive or more energy-consuming function needs to be performed based on actual needs, thereby flexibly and reliably implementing corresponding functions.

In some embodiments, the detection trigger event comprises at least one of a periodic trigger signal from the controller module, an abnormality detection signal from the sensor module, and a detection request signal from the external device.

The periodic trigger signal from the controller module refers to a signal set inside the controller module to trigger the execution of the high-accuracy detection at a fixed time interval, for example, the controller module transmits the periodic trigger signal cyclically at a time interval of every four hours.

The abnormality detection signal from the sensor module means that, when the sensor module is in the low-power operating mode, the sensor module is configured, for example, to perform a low-accuracy detection process that collects a small amount of data, collects data with low real-time, and consumes little power, and to perform a preliminary abnormality discrimination based on the detected data signal (for example, comparing it with a preset threshold). At this time, when the collected data signal (vibration/magnetic field/temperature/sound signal) is in the normal threshold range, the sensor module will not transmit any signal to the controller module, and when the collected data signal is out of the normal threshold range, the sensor module will, for example, transmit an abnormality detection signal to the controller module indicating that there is a significant abnormality of the device to be detected at this time and a high-accuracy detection process is needed.

It should be understood that embodiments of the present disclosure are not limited by the particular manner in which the abnormality detection signal is generated.

The detection request signal from the external device refers to a high-accuracy detection request from the external device (e.g., from an external device such as a gateway, or a client).

It will be understood that, according to practical needs, the detection trigger event also comprises, for example, a user manually operating a corresponding key or button of the sensor device to artificially initiate the relevant high-precision detection process.

Based on the above, in the present application, by setting the detection trigger event to include at least one of a periodic trigger signal from the controller module, an abnormality detection signal from the sensor module, and a detection request signal from the external device, the passive sensor device is enabled to adjust its operating mode in time and efficiently based on different situations from the external device, different modules inside, and the device to be detected and achieve a high-accuracy detection process for the device to be detected.

In some embodiments, in the high-power operating mode, the controller module is configured to determine a detection result of the device to be detected based on the detection signal, and transmit the detection result.

It should be understood that embodiments of the present disclosure are not limited by the particular manner of calculation by which the controller module determines the detection result based on the detection signal, nor by the particular manner of communication by which the controller module transmits the detection result.

In the present application, by setting the controller module to perform the calculation process, generate the detection results and transmit them to the outside only in the high-power operating mode, the functions with high-power consumption in the sensor device (such as a large number of data calculation and data communication) can be performed only when the system is at a high power level and there is a need for a high-accuracy detection, which is beneficial to the reduction in power consumption on the basis of achieving good and reliable detection.

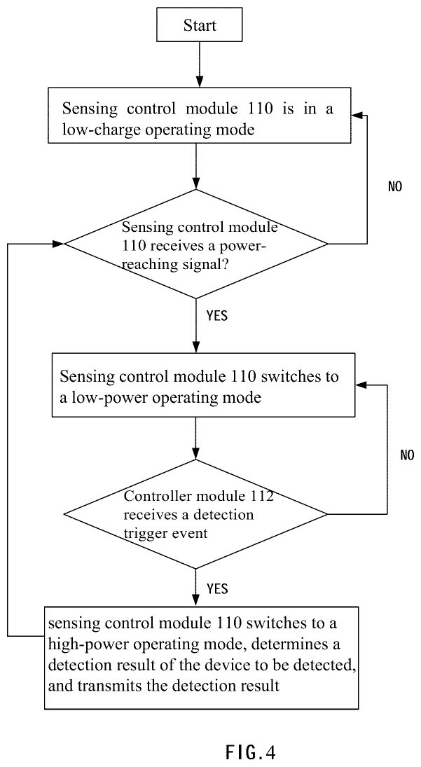

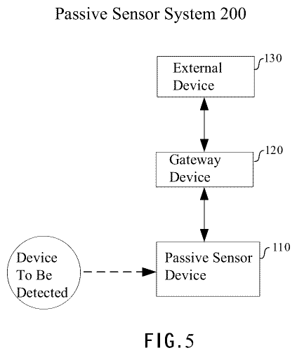

The above-described passive sensor device will be described in more detail next in connection with a specific implementation scenario. FIG. 4 shows a flow chart of a passive sensor device 100 for a motor according to an embodiment of the present disclosure.

Referring to FIG. 4, firstly, if the device to be detected is a motor, the passive sensor device 100 includes, for example, the sensing control module 110, the energy harvesting module 120, and the power management module 130 as shown in FIG. 1 above, and can implement the functions as described above. The power management module 130 includes, for example, a rectifier module, a regulator module, an energy tracking module, and a charge management module as described above. In addition, the sensing control module 110 includes, for example, the sensor module 111 and the controller module 112.

And wherein the passive sensor device is activated during normal operation of the motor, after which the sensing control module 110 will be set to be in the low-charge operating mode as described above, and the energy harvesting module 120 mounted on the main body of the motor (here, for example, a piezoelectric transducer) will convert the vibration energy from the device to be detected into alternating current energy, and when the vibration energy is converted into alternating current energy, which will be input to the power management module 130 as described above so that the power management module is powered up to enter an operating state. Thereafter, the power management module 130, as previously described, converts the alternating current energy to direct current energy and supplies power to the sensing control module 110 based on the direct current energy such that the sensing control module 110 operates in a low-charge operating mode (in which the controller module 112 is configured to be in a sleep mode and the sensor module 111 is configured to be in an unpowered mode, the sensor module will not be powered).

During the operation of the sensing control module 110 in the low-charge operating module, the energy storage element in the power management module 130 will be further charged and the energy will be further accumulated. When its electric energy/power reaches a preset standard (e.g., the current quantity of electric charge is greater than the preset quantity of electric charge threshold), the charging management module 134 of the power management module 130 will transmit the power-reaching signal to the sensing control module 110.

At this time, the sensing control module 110 in the low-power operating mode will switch from the low-charge operating mode to the low-power operating mode in the normal operating mode in response to the power-reaching signal (the specific performing function of this mode of operation is as described above). At this time, the sensor module 111 performs a low-accuracy detection process, and the controller module 112 is configured to receive only the detection trigger event, without receiving other signals, without signal processing, and without transmitting data to the outside.

The detection trigger event includes a periodic trigger signal from the controller module, an abnormality detection signal from the sensor module, and a detection request signal from an external device. When the sensing control module 110 (its internal controller module 112) receives one of the three signals, the sensing control module 110 switches from the low-power operating mode to the high-power operating mode, specifically, the controller module 112 switches from the low-power operating mode to the high-power operating mode and the sensor module 111 switches to the high-power operating mode. In this high-power operating mode, the sensor module 111 will perform the aforementioned high-accuracy detection process, and transmit a corresponding detection signal to the controller module 112, which will determine a detection result of the device to be detected based on receiving the detection signal and based on the detection signal, and transmit the detection result to the external device.

Further, after transmitting the detection result, the sensing control module 110 (e.g., the controller module thereof) may, for example, communicate with the power management module 130 and transmit a power detection request signal (requesting the power management module 130 to detect the current quantity of electric charge of the energy storage element again). The power management module 130 detects the current quantity of electric charge of the energy storage element in response to the request signal, compares the current quantity of electric charge of the energy storage element with a preset quantity of electric charge threshold, and transmits a power-reaching signal to the sensing control module in the case that the current quantity of electric charge is greater than the preset quantity of electric charge threshold. The following processes are the same as the foregoing, and will not be repeated here.

According to another aspect of the present disclosure, a passive sensor system 200 is provided. FIG. 5 shows a schematic diagram of a passive sensor system 200 according to embodiments of the disclosure.

With reference to FIG. 5, the passive sensor system 200 comprises, for example, the passive sensor device 100, the gateway device 110, and the external device 120 as described above.

The passive sensor device 100 has, for example, the structure described above and is capable of performing the functions described above.

The gateway device 110 is configured to receive the detection result from the passive sensor device 100 and transmit the detection result to the external device 120. It should be understood that the present disclosure is not limited by the particular type of gateway device and its particular manner of communication and communication protocol.

The external device 120 includes, for example, at least one of a cloud platform and a user device, and is configured to receive the detection result from the gateway device, and display or store the detection result.

In some embodiments, one device (master device) of the external devices can act as a gateway device, which receives the detection result from the passive sensor device and distributes the detection result further to other external devices (slave devices).

The gateway device 110 is further configured to receive instruction information from the external device 120 and transmit the instruction information to the passive sensor device 100.

The instruction information may for example comprise the aforementioned detection request signal, or may also comprise other instruction signals or configuration signals to the passive sensor device.

Based on the above, in this application, the passive sensor system comprises the passive sensor device, the gateway device and the external device as described above, so that the detection process of the device to be detected can be implemented in a simple and convenient manner while solving the problem of complicated wiring or regular replacement of the current active sensor. Meanwhile, by providing two-way data transmission and reception among the gateway device, the external device, and the passive sensor device, the storage and display of the detection result can be well realized, and the passive sensor device can be well controlled.

Although in the above figures, the various sub-parts are presented as separate modules, a person skilled in the art may understand that the above device modules may be implemented as separate hardware devices or may be integrated as one or more hardware devices. The specific implementation of different hardware devices should not be taken as a factor in limiting the scope of the present disclosure as long as the principles described herein can be implemented.

The present application uses specific words to describe embodiments of the present application. Reference to “first/second embodiment,” “an embodiment,” and/or “some embodiments” means a feature, structure, or characteristic in connection with at least one embodiment of the present disclosure. Therefore, it should be emphasized and noted that two or more references to “an embodiment”, “one embodiment” or “an alternative embodiment” in various places throughout this specification are not necessarily referring to the same embodiment. Furthermore, the certain features, structures or characteristics may be combined as suitable in one or more embodiments of the application.

Moreover, one skilled in the art will appreciate that aspects of the present application may be illustrated and described in terms of a number of patentable categories or instances, including any new and useful process, machine, manufacture, or combination of matter, or any new and useful improvement thereof. Accordingly, aspects of the present application may be performed entirely by hardware, entirely by software (including firmware, resident software, micro-code, etc.), or by a combination of hardware and software. The above hardware or software may each be referred to as a “data block,” “module,” “engine,” “unit,” “component,” or “system.” Furthermore, aspects of the present disclosure may be embodied as a computer product embodied in one or more computer-readable medium(s) including computer-readable program code.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or extremely formal sense unless expressly so defined herein.

The foregoing is illustrative of the present disclosure and is not to be considered as limiting thereof. Although several exemplary embodiments of this present disclosure have been described, those skilled in the art will readily appreciate that many modifications are possible in the exemplary embodiments without departing from the novel teachings and advantages of this present disclosure. Accordingly, all such modifications are intended to be included within the scope of this present disclosure as defined in the claims. It is to be understood that the above is illustrative of the present disclosure and is not to be considered limited to the specific embodiments, and that modifications to the disclosed embodiments, as well as other embodiments, are intended to be included within the scope of the appended claims. The present disclosure is defined by the claims and their equivalents.

1. A passive sensor device comprising:
a sensing control module configured to operatively perform a detection process on a device to be detected and generate a detection result;
an energy harvesting module mounted on a main body of the device to be detected and configured to convert the harvested vibration energy from the device to be detected into alternating current energy; and
a power management module configured to receive the alternating current energy from the energy harvesting module, convert the alternating current energy to direct current energy, and supply power to the passive sensor device based on the direct current energy.

2. The passive sensor device of claim 1, wherein the power management module comprises:
a rectifier module configured to convert the alternating current energy into first direct current energy;
a regulator module configured to receive the first direct current energy from the rectifier module, perform a voltage regulation on the first direct current energy to generate second direct current energy;
an energy tracking module configured to receive the second direct current energy from the regulator module and charge an energy storage element based on the second direct current energy; and
a charging management module configured to supply power to the passive sensor device by using direct current energy in the energy storage element.

3. The passive sensor device of claim 2, wherein the charging management module is further configured to:
detect current quantity of electric charge of the energy storage element;
compare the current quantity of electric charge of the energy storage element with a preset quantity of electric charge threshold, and transmit a power-reaching signal to the sensing control module in the case that the current quantity of electric charge is greater than the preset quantity of electric charge threshold.

4. The passive sensor device of claim 3, wherein the sensing control module is pre-configured to be in a low-charge operating mode, and the sensing control module is further configured to:
receive the power-reaching signal from the charge management module; and
switch from the low-charge operating mode to a normal operating mode in response to the power-reaching signal, wherein power consumption in the normal operating mode is higher than that in the low-charge operating mode.

5. The passive sensor device of claim 4, wherein the sensing control module comprises:
a sensor module configured to operatively detect a performance state of the device to be detected, and generate a detection signal; and
a controller module configured to operatively receive the detection signal and determine a detection result of the device to be detected based on the detection signal.

6. The passive sensor device of claim 5, wherein, in the low-charge operating mode, the controller module is configured to be in a sleep mode and the sensor module is configured to be in an unpowered mode; and wherein the controller module and the sensor module switch to a low-power operating mode upon receiving the power-reaching signal.

7. The passive sensor device of claim 6, wherein when the controller module and the sensor module are in the low-power operating mode, and the controller module and the sensor module are configured to switch from the low-power operating mode to a high-power operating mode when the controller module receives a detection trigger event.

8. The passive sensor device of claim 7, wherein the detection trigger event comprises at least one of a periodic trigger signal from the controller module, an abnormality detection signal from the sensor module, and a detection request signal from an external device.

9. The passive sensor device of claim 7, wherein, in the high-power operating mode, the controller module is configured to determine the detection result of the device to be detected based on the detection signal, and transmit the detection result.

10. A passive sensor system comprising:
a passive sensor device according to claim 1;
a gateway device configured to receive the detection result from the passive sensor device and transmit the detection result to an external device; and
the external device comprising at least one of a cloud platform and a user device, and configured to receive the detection result from the gateway device, and display or store the detection result;
wherein the gateway device is further configured to receive instruction information from the external device and transmit the instruction information to the passive sensor device.

11. A passive sensor system comprising:
a passive sensor device according to claim 9;
a gateway device configured to receive the detection result from the passive sensor device and transmit the detection result to an external device; and
the external device comprising at least one of a cloud platform and a user device, and configured to receive the detection result from the gateway device, and display or store the detection result;
wherein the gateway device is further configured to receive instruction information from the external device and transmit the instruction information to the passive sensor device.
